(19) United States
(12) Patent Application Publication
(10) Pub. No.: US 2012/0205520 A1
(43) Pub. Date: Aug. 16, 2012

(54) IMAGE SENSOR AND SENSING METHOD THEREOF

(75) Inventors: Chih-Cheng Hsieh, Hsinchu County (TW); Shang-Fu Yeh, Pingtung County (TW); Ka-Yi Yeh, Hsinchu City (TW)

(73) Assignee: INDUSTRIAL TECHNOLOGY RESEARCH INSTITUTE, Hsinchu (TW)

(21) Appl. No.: 13/086,362

(22) Filed: Apr. 13, 2011

(30) Foreign Application Priority Data
Feb. 14, 2011 (TW) 100104778

(51) Int. Cl. H01L 27/146

(52) U.S. Cl. 250/208.1; 257/292; 257/E27.133

(57) ABSTRACT

An image sensor including a pixel array is provided. The pixel array includes R×S sub-pixel arrays. The sub-pixel array includes P×Q pixels. Each pixel includes a photodiode, a first transistor, a second transistor, a third transistor, a fourth transistor, and a fifth transistor. The gate of the second transistor is coupled to a row control signal. The second source/drain electrode of the second transistor is coupled to a column control signal. The gate electrode of the third transistor is coupled to a reset signal. The second source/drain electrode of the third transistor is coupled to a column voltage reset signal. The gate electrode of the fifth transistor is coupled to a row select signal. The sub-pixel array uses the row control signal, the column control signal, the column voltage reset signal, and the row select signal to select an output the sensing signal of one of the pixels.

### CROSS-REFERENCE TO RELATED APPLICATION

This application claims the priority benefit of Taiwan application serial no. 100104778, filed Feb. 14, 2011. The entirety of the above-mentioned patent application is hereby incorporated by reference herein and made a part of this specification.

### TECHNICAL FIELD

The disclosure relates to an optical sensor. Particularly, the disclosure relates to an image sensor.

### BACKGROUND

As computers and communication products are quickly developed, various electronic products are continually developed, and in the semiconductor industry of recent years, in order to meet consumers' demands for lightness, thinness, shortness and smallness of the electronic products, chip packaging processes deviate from conventional techniques and are developed towards processes with high power, high density and low cost.

In order to meet the above development trend, a three-dimensional stacked integrated circuit (3DIC) technique is developed to become a main trend in future development of the semiconductor industry and become a focus of global concern. The 3DIC technique is to stack two-dimensional (2D) chips into a 3D chip and use through silicon vias (TSVs) for electric connection, and signal transmission is changed from original planar transmission to 3D transmission, which can greatly reduce a signal transmission path and effectively reduce signal transmission delay and energy loss, and can respectively implement technique optimisation and process selection of the 2D chips of each layer. In this way, demands for product profile, quality and cost are met.

A complementary metal oxide semiconductor (CMOS) image sensor is a product suitable of applying the 3DIC technique. The CMOS image sensor can be implemented by a 3D image sensing chip, and a structure thereof is composed of a pixel array on a top layer, a read circuit and an analog to digital converter (ADC) of a second layer, and an image processor of a third layer. If a conventional CMOS image sensor reading method is used, all pixels on a same column share a same column read circuit, when the pixel array of the top layer is to transmit a signal to the column read circuit of the second layer, considering a circuit layout, a pixel pitch has to be greater than or equal to a pitch of chip stacking devices, for example, TSVs. Therefore, the pitch of the chip stacking devices limits the pixel pitch, and if the pixel pitch cannot be reduced, in high-resolution applications of the CMOS image sensor, an area size of a photo sensing chip is excessive, which may increase the product cost and decrease a production yield.

### SUMMARY

An exemplary embodiment of an image sensor including a pixel array is introduced herein. The pixel array includes R×S sub-pixel arrays SP(i,j), and each sub-pixel array SP(i,j) includes P×Q pixels PI(x,y), where R and S are integers greater than 1, P, Q, i, j, x, y are all integers greater than or equal to 1, i is smaller than or equal to R, j is smaller than or equal to S, x is smaller than or equal to P, and y is smaller than or equal to Q. Each pixel PI(x,y) includes a photodiode, a first transistor, a second transistor, a third transistor, a fourth transistor, and a fifth transistor.

The photodiode is used for sensing a light source to obtain a sensing signal. The first transistor includes a first source/drain, a second source/drain and a gate, where the first source/drain of the first transistor is coupled to the photodiode, and the second source/drain of the first transistor is coupled to a node. The second transistor includes a first source/drain, a second source/drain and a gate. The first source/drain of the second transistor is coupled to the gate of the first transistor, the gate of the second transistor is coupled to a row control signal Rtg[n], and the second source/drain of the second transistor is coupled to a column control signal Ctg[m], where n and m are all integers greater than or equal to 1, n is smaller than or equal to P, and m is smaller than or equal to Q. The third transistor includes a first source/drain, a second source/drain and a gate. The first source/drain of the third transistor is coupled to the node, the gate of the third transistor is coupled to a reset signal Rreset[n], and the second source/drain of the third transistor is coupled to a column voltage reset signal Cvrst[m]. The fourth transistor includes a first source/drain, a second source/drain and a gate. The gate of the fourth transistor is coupled to the node, and the second source/drain of the fourth transistor is coupled to a power voltage. The fifth transistor includes a first source/drain, a second source/drain and a gate. The first source/drain of the fifth transistor is coupled to a signal output terminal, the gate of the fifth transistor is coupled to a row select signal Rsel[n], and the second source/drain of the fifth transistor is coupled to the first source/drain of the fourth transistor. Where, the sub-pixel array SP(i,j) uses the row control signal Rtg[n], the column control signal Ctg[m], the column voltage reset signal Cvrst[m], and the row select signal Rsel[n] to select and output the sensing signal of a pixel PI(n,m).

An exemplary embodiment of a sensing method of an image sensor is introduced herein, where the image sensor includes a pixel array. The pixel array includes R×S sub-pixel arrays SP(i,j). Each sub-pixel array SP(i,j) includes P×Q pixels PI(x,y), and each pixel PI(x,y) includes a photodiode, a node and a signal output terminal. Each pixel is connected to a row select signal Rsel[n], a row control signal Rtg[n], a reset signal Rreset[n], a column control signal Ctg[m] and a column voltage reset signal Cvrst[m], where R and S are integers greater than 1, P, Q, i, j, n, m, x, y are all integers greater than or equal to 1, i is smaller than or equal to R, j is smaller than or equal to S, n and x are smaller than or equal to P, and m and y are smaller than or equal to Q.

The sensing method includes following steps. After the row select signal Rsel[n] is enabled, the reset signal Rreset[n] sends a pulse to provide a first potential of the column voltage reset signal Cvrst[m] to the node, and a voltage of the signal output terminal follows a voltage of the node. After the row control signal Rtg[n] is enabled, the column control signal Ctg[m] sends a pulse to conduct the photodiode and the node, so that a sensing signal of the photodiode is presented at the signal output terminal. The reset signal Rreset[n] sends another pulse to provide a second potential of the column voltage reset signal Cvrst[m] to the node, and the voltage of the signal output terminal is no longer related to the sensing signal of the photodiode.

Another exemplary embodiment of a sensing method of an image sensor is introduced herein, wherein the sensing method includes following steps. A pixel array is provided, where the pixel array includes R×S sub-pixel arrays SP(i,j), each sub-pixel array SP(i,j) includes P×Q pixels PI(x,y), and each pixel PI(x,y) is connected to a row select signal Rsel[n], a row control signal Rtg[n], a reset signal Rreset[n], a column control signal Ctg[m] and a column voltage reset signal Cvrst[m], where R and S are integers greater than 1, P, Q, i, j, n, m, x, y are all integers greater than or equal to 1, i is smaller than or equal to R, j is smaller than or equal to S, n and x are smaller than or equal to P, and m and y are smaller than or equal to Q. Moreover, each pixel PI(x,y) of the sub-pixel array SP(i,j) is connected to a same signal output terminal. In addition, after the row select signal Rsel[n] is enabled, the row control signal Rtg[n] is enabled and the column voltage reset signal Cvrst[m] is set to a first potential. The reset signal Rreset[n] sends a pulse, and a reset signal of the pixel PI(n,m) is output to the signal output terminal. Finally, the column control signal Ctg[m] sends another pulse, and a sensing signal of the pixel PI(n,m) is output to the signal output terminal.

Another exemplary embodiment of a sensing method of an image sensor is introduced herein. The image sensor includes a pixel array. The pixel array includes a plurality of sub-pixel arrays, and each sub-pixel array includes a plurality of pixels. The sensing method can be described as follows. Each pixel is connected to a same signal output terminal of the belonged sub-pixel array. A row select signal, a row control signal and a column voltage reset signal are generated. Reset sensing is performed according to a reset signal. Moreover, a sensing signal of a light source is sensed. A column control signal is used for outputting the sensing signal to the signal output terminal. In the sensing method, the sub-pixel array uses the row select signal, the row control signal, the column voltage reset signal, and the column control signal to select and output the sensing signal of one of the pixels.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a complementary metal oxide semiconductor (CMOS) image sensor according to an exemplary embodiment.

FIG. 2 is a schematic diagram of control circuits of the sub-pixel arrays according to an exemplary embodiment.

FIG. 3 is a schematic diagram of a sub-pixel array SP(i,j) according to an exemplary embodiment.

FIG. 4 is a schematic diagram illustrating a circuit structure of any pixel PI(x,y) of FIG. 3.

FIG. 5 is a signal timing waveform diagram of the sub-pixel array SP(i,j) of FIG. 3.

FIG. 6 is a flowchart illustrating a sensing method of a CMOS image sensor according to an exemplary embodiment.

FIG. 7 is a flowchart illustrating a sensing method of a CMOS image sensor according to an exemplary embodiment.

FIG. 8 is a flowchart illustrating a sensing method of a CMOS image sensor according to an exemplary embodiment.

### DETAILED DESCRIPTION

A three-dimensional (3D) image sensing chip is adapted to a complementary metal oxide semiconductor (CMOS) image sensor, and after various sub-circuits in the conventional CMOS image sensor that include a pixel array, an analog front end (AFE), an analog to digital converter (ADC) and an image signal processor (ISP) are respectively fabricated through suitable semiconductor processes, 3D chip stacking devices are used to stack the individual 2D chips into the 3D image sensing chip.

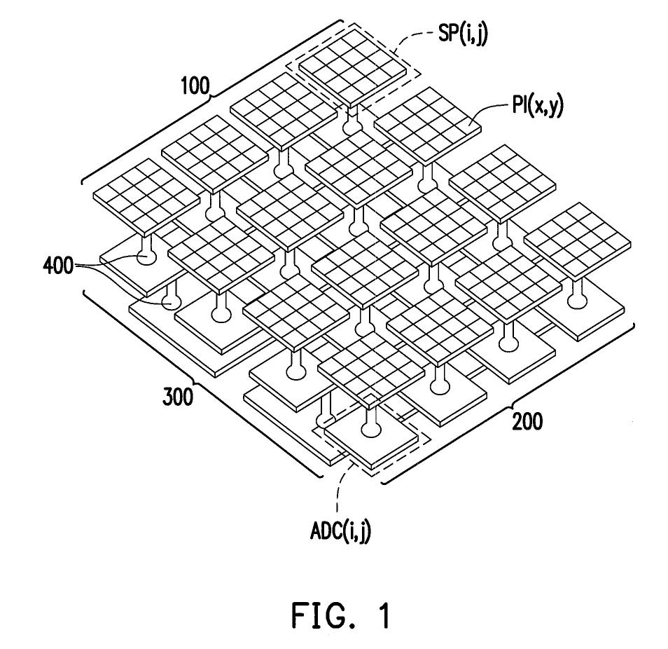

In the disclosure, a CMOS image sensor according to an exemplary embodiment is disclosed as that shown in FIG. 1. FIG. 1 is a schematic diagram of a CMOS image sensor. Referring to FIG. 1, the CMOS image sensor includes a pixel array 100, an analog to digital converter array 200, an image signal processor 300, and 3D chip stacking devices 400. The pixel array 100 includes R×S sub-pixel arrays SP(i,j), and each sub-pixel array SP(i,j) includes P×Q pixels PI(x,y). The analog to digital converter array 200 includes R×S analog to digital converters ADC(i,j), where R and S are integers greater than 1, P, Q, i, j, x, y are all integers greater than or equal to 1, is smaller than or equal to R, j is smaller than or equal to S, x is smaller than or equal to P, and y is smaller than or equal to Q.

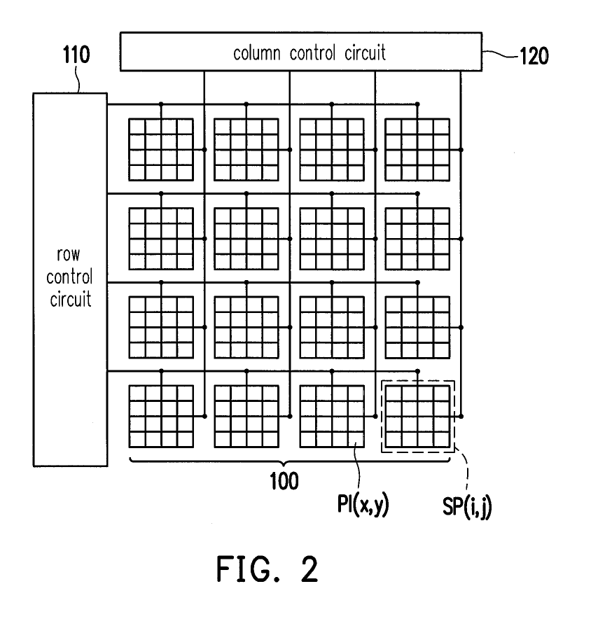

In the CMOS image sensor, the sub-pixel arrays SP(i,j) are operated in parallel. To achieve the parallel operation, the sub-pixel arrays SP(i,j) are all connected to a row control circuit and a column control circuit, and the row control circuit and the column control circuit generate signals to control the sub-pixel arrays SP(i,j), as that shown in FIG. 2. FIG. 2 is a schematic diagram of control circuits of the sub-pixel arrays. Referring to FIG. 1 and FIG. 2, each of the sub-pixel arrays SP(i,j) is connected to a row control circuit 110 and a column control circuit 120, so that in a same timing, the sub-pixel arrays SP(i,j) receive the same signals and are operated in collaboration to achieve a high bandwidth of the 3D image sensing chip.

Moreover, the row control circuit 110 and the column control circuit 120 can further control the sub-pixel arrays SP(i,j) to sequentially read a signal of each pixel PI(x,y) in the sub-pixel arrays SP(i,j), and each time each sub-pixel array SP(i,j) only sends the signal of one of the pixels PI(x,y), and the signal is transmitted to the analog to digital converter ADC(i,j) of the analog to digital converter array 200 of a next layer through the 3D chip stacking device 400, for example, through silicon vias (TSVs), redistribution layer (RDL) wires, or micro-bumps, etc.

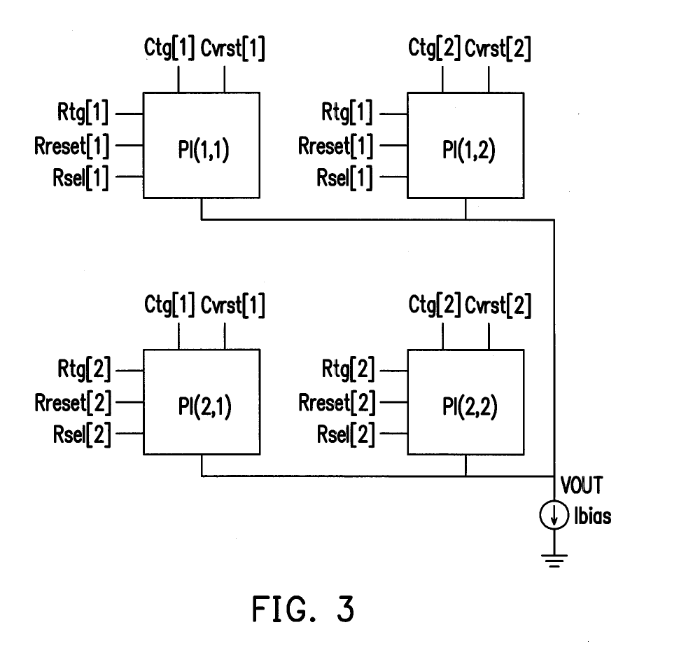

An exemplary embodiment is provided below to described in detail how the sub-pixel array SP(i,j) sequentially outputs the signal of each pixel PI(x,y). FIG. 3 is a schematic diagram of a sub-pixel array SP(i,j). The sub-pixel array SP(i,j) includes 2×2 pixels PI(x,y) (P=2, Q=2, x is smaller than or equal to 2, and y is smaller than or equal to 2), though the disclosure is not limited thereto, and in other embodiments, P and Q can be determined according to an actual design requirement.

Referring to FIG. 3, each pixel PI(x,y) in the sub-pixel array SP(i,j) is connected to a same signal output terminal VOUT, and the row control circuit (for example, the row control circuit 110 of FIG. 2) generates a reset signal Rreset[n], a row control signal Rtg[n] and a row select signal Rsel[n] for outputting to the pixels of an n^{th} row in the sub-pixel array SP(i,j). The column control circuit (for example, the column control circuit 120 of FIG. 2) generates a column control signal Ctg[m] and a column voltage reset signal Cvrst[m] for transmitting to the pixels of an m^{th} column in the sub-pixel array SP(i,j), where n, m are all integers greater than or equal to 1, n is smaller than or equal to P, and m is smaller than or equal to Q. In the present exemplary embodiment, signals Rreset[1], Rtg[1] and Rsel[1] are transmitted to the pixel PI(1,1) and the pixel PI(1,2), signals Rreset[2], Rtg[2] and Rsel[2] are transmitted to the pixel PI(2,1) and the pixel PI(2,2), signals Ctg[1] and Cvrst[1] are transmitted to the pixel PI(1,1) and the pixel PI(2,1), and signals Ctg[2] and Cvrst[2] are transmitted to the pixel PI(1,2) and the pixel PI(2,2).

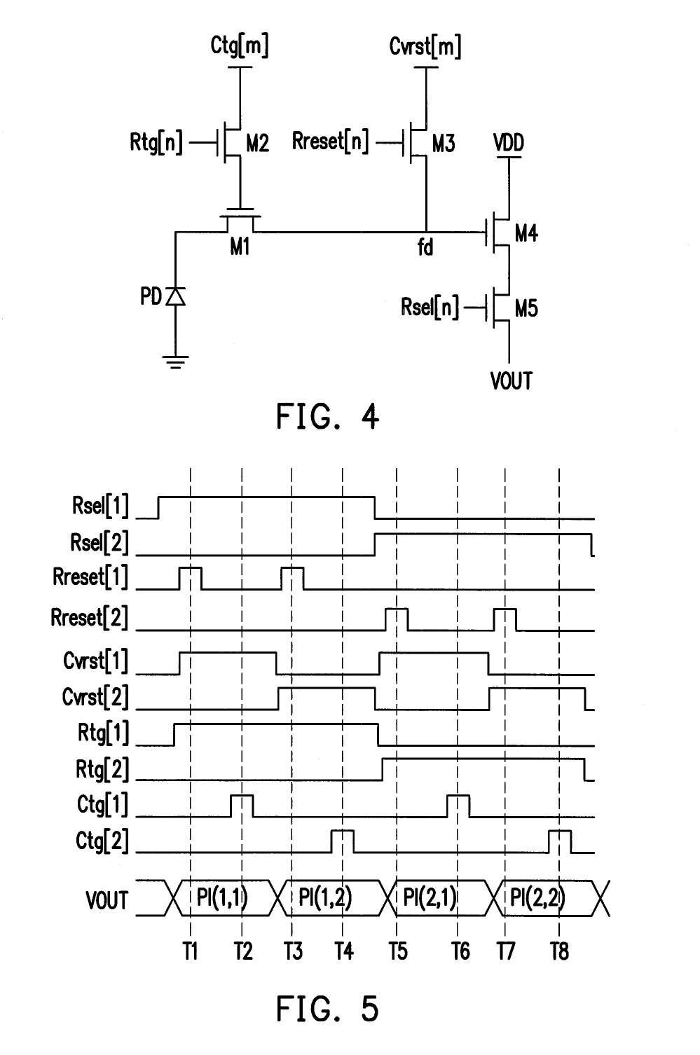

FIG. 4 is a schematic diagram illustrating a circuit structure of any pixel PI(x,y) of FIG. 3. Referring to FIG. 3 and FIG. 4, the pixel PI(x,y) includes a photodiode PD, a first transistor M1, a second transistor M2, a third transistor M3, a fourth transistor M4 and a fifth transistor M5. The first transistor M1, the second transistor M2, the third transistor M3, the fourth transistor M4 and the fifth transistor M5 respectively include a first source/drain, a second source/drain and a gate.

The photodiode PD is used for sensing a light source to obtain a sensing signal. The first source/drain of the first transistor M1 is coupled to the photodiode PD, the second source/drain of the first transistor M1 is coupled to a node fd. The first source/drain of the second transistor M2 is coupled to the gate of the first transistor M1, the gate of the second transistor M2 is coupled to the row control signal Rtg[n], and the second source/drain of the second transistor M2 is coupled to the column control signal Ctg[m]. The first source/drain of the third transistor M3 is coupled to the node fd, the gate of the third transistor M3 is coupled to the reset signal Rreset[n], and the second source/drain of the third transistor M3 is coupled to a column voltage reset signal Cvrst[m]. The gate of the fourth transistor M4 is coupled to the node fd, and the second source/drain of the fourth transistor M4 is coupled to a power voltage VDD. The first source/drain of the fifth transistor M5 is coupled to a signal output terminal VOUT, the gate of the fifth transistor M5 is coupled to the row select signal Rsel[n], and the second source/drain of the fifth transistor M5 is coupled to the first source/drain of the fourth transistor M4.

For example, the first, the second, the third, the fourth and the fifth transistors can be N-type metal oxide semiconductor transistors, though the disclosure is not limited thereto. In an exemplary embodiment, the node fd is regarded to be connected to a parasitic floating capacitor for storing charges, and presents the sensing signal generated by the photodiode PD along with a charge flow of the photodiode PD. The fourth transistor M4 can be a source follower transistor, i.e. when the fourth transistor M4 is normally operated, a voltage at the first source/drain of the fourth transistor M4 follows a voltage of the node fd.

According to the above description, FIG. 5 is a signal timing waveform diagram of the sub-pixel array SP(i,j) of FIG. 3. In the following descriptions, 8 timings are divided to describe in detail how the sub-pixel array SP(i,j) sequentially outputs the signal of each of the pixels PI(x,y) with reference of FIG. 3, FIG. 4 and FIG. 5.

In a first timing T1, after the row select signal Rsel[1] is enabled (which, for example, has a high potential in the present exemplary embodiment), the row control signal Rtg[1] is enabled, and the column voltage reset signal Cvrst[1] is set to a first potential, which is a high potential in the present exemplary embodiment, and the column voltage reset signal Cvrst[2] is set to a second potential, which is a low potential in the present exemplary embodiment. The reset signal Rreset[1] sends a pulse to provide the first potential of the column voltage reset signal Cvrst[1] to the node fd of the pixel PI(1,1), and provide the second potential of the column voltage reset signal Cvrst[2] to the node fd of the pixel PI(1,2). Therefore, the voltage of the node fd of the pixel PI(1,1) is far greater than the voltage of the node fd of the pixel PI(1,2), and since the row select signal Rsel[2] is disabled, the fifth transistors M5 of the pixels PI(2,1) and PI(2,2) are turned off, so that the voltage of the signal output terminal VOUT follows the voltage of the node fd of the pixel PI(1,1), and a current Ibias flows through the pixel PI(1,1). Therefore, the reset signal of the pixel PI(1,1) is output to the signal output terminal VOUT.

In a second timing T2, the row control signal Rtg[1], the column voltage reset signal Cvrst[1] and the row select signal Rsel[1] are maintained unchanged, and the column control signal Ctg[1] sends a pulse to conduct the photodiode PD and the node fd, so that the sensing signal of the pixel PI(1,1) is output to the signal output terminal VOUT.

In a third timing T3, the row select signal Rsel[1] and the row control signal Rtg[1] are maintained unchanged, the column voltage reset signal Cvrst[1] is set to the second potential, and the column voltage reset signal Cvrst[2] is set to the first potential. The reset signal Rreset[1] sends a pulse to provide the first potential of the column voltage reset signal Cvrst[2] to the node fd of the pixel PI(1,2), and the voltage of the signal output terminal VOUT follows the voltage of the node fd of the pixel PI(1,2). Now, since the column voltage reset signal Cvrst[1] is set to the second potential, as the reset signal Rreset[1] sends the pulse, the second potential of the column voltage reset signal Cvrst[1] is provided to the node fd of the pixel PI(1,1), and the voltage of the signal output terminal VOUT is no longer related to the sensing signal of the photodiode of the pixel PI(1,1). Therefore, the voltage of the node fd of the pixel PI(1,2) is far greater than the voltage of the node fd of the pixel PI(1,1), and the current Ibias flows through the pixel PI(1,2). Therefore, the reset signal of the PI(1,2) is output to the signal output terminal VOUT.

In a fourth timing T4, the row control signal Rtg[1], the column voltage reset signal Cvrst[2] and the row select signal Rsel[1] are maintained unchanged, and the column control signal Ctg[2] sends a pulse to conduct the photodiode PD and the node fd, so that the sensing signal of the pixel PI(1,2) is output to the signal output terminal VOUT.

In a fifth timing T5, after the row select signal Rsel[2] is enabled, the row control signal Rtg[2] is enabled, and the column voltage reset signal Cvrst[1] is set to the first potential, and the column voltage reset signal Cvrst[2] is set to the second potential. The reset signal Rreset[2] sends a pulse to provide the first potential of the column voltage reset signal Cvrst[1] to the node fd of the pixel PI(2,1), and provide the second potential of the column voltage reset signal Cvrst[2] to the node fd of the pixel PI(2,2). Therefore, the voltage of the node fd of the pixel PI(2,1) is far greater than the voltage of the node fd of the pixel PI(2,2), and since the row select signal Rsel[1] is disabled, the fifth transistors M5 of the pixels PI(1,1) and PI(1,2) are turned off, so that the voltage of the signal output terminal VOUT follows the voltage of the node fd of the pixel PI(2,1), and the current Ibias flows through the pixel PI(2,1). Therefore, the reset signal of the pixel PI(2,1) is output to the signal output terminal VOUT.

In a sixth timing T6, the row control signal Rtg[2], the column voltage reset signal Cvrst[1] and the row select signal Rsel[2] are maintained unchanged, and the column control signal Ctg[1] sends a pulse to conduct the photodiode PD and the node fd, so that the sensing signal of the pixel PI(2,1) is output to the signal output terminal VOUT.

In a seventh timing T7, the row select signal Rsel[2] and the row control signal Rtg[2] are maintained unchanged, the column voltage reset signal Cvrst[1] is set to the second potential, and the column voltage reset signal Cvrst[2] is set to the first potential. The reset signal Rreset[2] sends a pulse to provide the first potential of the column voltage reset signal Cvrst[2] to the node fd of the pixel PI(2,2), and the voltage of the signal output terminal VOUT follows the voltage of the node fd of the pixel PI(2,2). Now, since the column voltage reset signal Cvrst[1] is set to the second potential, as the reset signal Rreset[2] sends the pulse, the second potential of the column voltage reset signal Cvrst[1] is provided to the node fd of the pixel PI(2,1), and the voltage of the signal output terminal VOUT is no longer related to the sensing signal of the photodiode of the pixel PI(2,1). Therefore, the voltage of the node fd of the pixel PI(2,2) is far greater than the voltage of the node fd of the pixel PI(2,1), and the current Ibias flows through the pixel PI(2,2). Therefore, the reset signal of the PI(2,2) is output to the signal output terminal VOUT.

In an eighth timing T8, the row control signal Rtg[2], the column voltage reset signal Cvrst[2] and the row select signal Rsel[2] are maintained unchanged, and the column control signal Ctg[2] sends a pulse to conduct the photodiode PD and the node fd, so that the sensing signal of the pixel PI(2,2) is output to the signal output terminal VOUT.

As described above, the sub-pixel array SP(i,j) sequentially outputs the reset signal and the sensing signal of each pixel PI(x,y). Namely, the sub-pixel array SP(i,j) uses the row control signal Rtg[n], the column control signal Ctg[m], the column voltage reset signal Cvrst[m], and the row select signal Rsel[n] to select and output the sensing signal of the pixel PI(n,m).

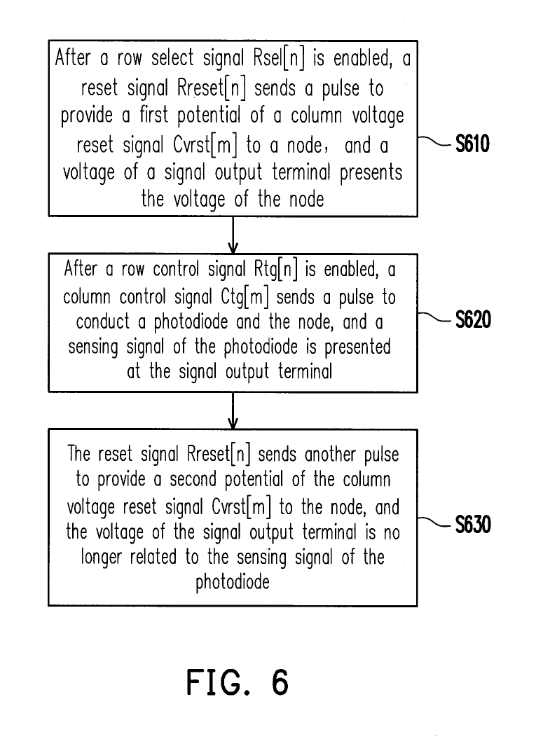

Another exemplary embodiment is provided below to describe in detail an operation method of the circuit structure of the pixel PI(x,y) of FIG. 4 with reference of FIG. 6. FIG. 6 is a flowchart illustrating a sensing method of a CMOS image sensor, where the CMOS image sensor is the same to the CMOS image sensor of the aforementioned exemplary embodiment, so that detailed descriptions thereof are not repeated.

Referring to FIG. 4 and FIG. 6, in step S610, after the row select signal Rsel[n] is enabled, the reset signal Rreset[n] sends a pulse to provide the first potential of the column voltage reset signal Cvrst[m] to the node fd. In the present exemplary embodiment, the node fd is regarded to be connected to a parasitic floating capacitor, and the fourth transistor M4 can be a source follower transistor, i.e. when the fourth transistor M4 is normally operated, a voltage at the first source/drain of the fourth transistor M4 follows a voltage of the node fd. Therefore, the voltage of the signal output terminal VOUT presents the voltage of the node. In step S620, after the row control signal Rtg[n] is enabled, the column control signal Ctg[m] sends a pulse to conduct the photodiode PD and the node fd, and a sensing signal of the photodiode PD is presented at the signal output terminal VOUT through the source follower transistor. In step S630, the reset signal Rreset[n] sends another pulse to provide the second potential of the column voltage reset signal Cvrst[m] to the node fd, and the voltage of the signal output terminal VOUT is no longer related to the sensing signal of the photodiode PD. The operation method of the circuit structure of the pixel PI(x,y) is described as above.

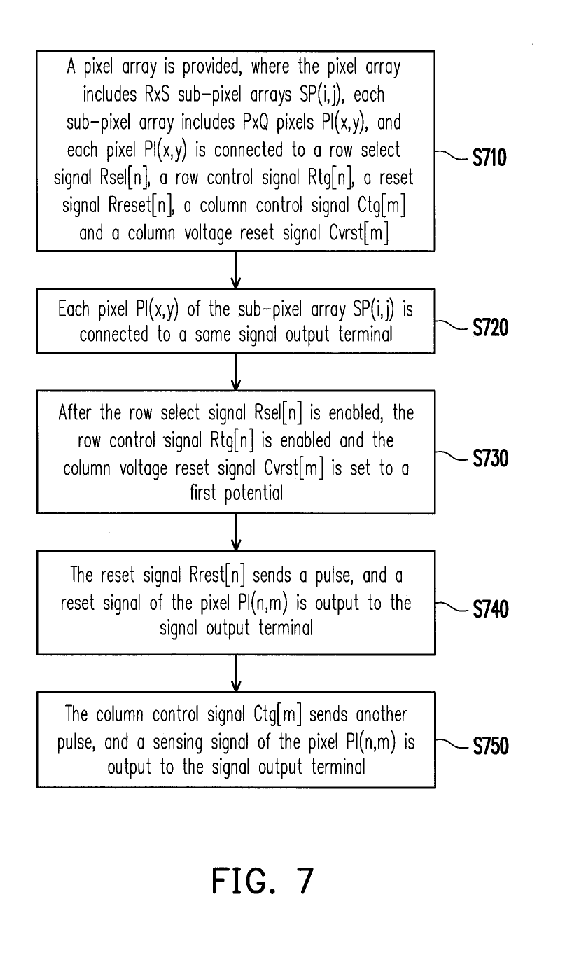

According to another aspect, FIG. 7 is a flowchart illustrating a sensing method of a CMOS image sensor. Referring to FIG. 7, in step S710, a pixel array is provided, where the pixel array includes R×S sub-pixel arrays SP(i,j), each sub-pixel array includes P×Q pixels PI(x,y), and each pixel PI(x,y) is connected to a row select signal Rsel[n], a row control signal Rtg[n], a reset signal Rreset[n], a column control signal Ctg[m] and a column voltage reset signal Cvrst[m], where R and S are integers greater than 1, P, Q, i, j, n, m, x, y are all integers greater than or equal to 1, i is smaller than or equal to R, j is smaller than or equal to S, n and x are smaller than or equal to P, and m and y are smaller than or equal to Q. In step S720, each pixel PI(x,y) of the sub-pixel array SP(i,j) is connected to a same signal output terminal. In step S730, after the row select signal Rsel[n] is enabled, the row control signal Rtg[n] is enabled and the column voltage reset signal Cvrst[m] is set to a first potential. In step S740, the reset signal Rreset[n] sends a pulse, and a reset signal of the pixel PI(n,m) is output to the signal output terminal. In step S750, the column control signal Ctg[m] sends another pulse, and a sensing signal of the pixel PI(n,m) is output to the signal output terminal.

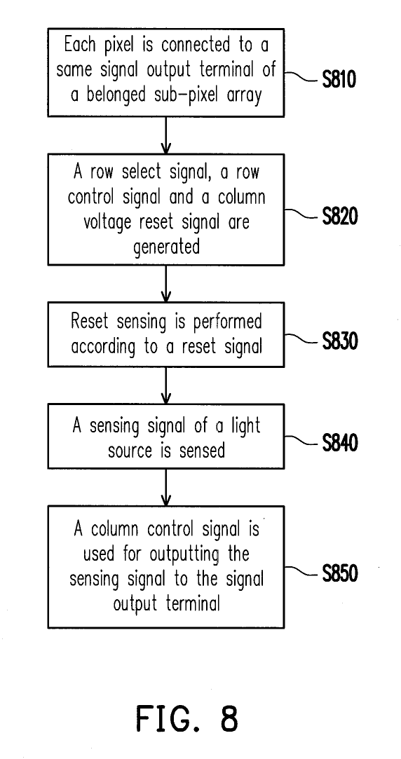

According to still another aspect, FIG. 8 is a flowchart illustrating a sensing method of a CMOS image sensor. The CMOS image sensor includes a pixel array. The pixel array includes a plurality of sub-pixel arrays, and each sub-pixel array includes a plurality of pixels. Referring to FIG. 8, the sensing method includes following steps. In step S810, each pixel is connected to a same signal output terminal of the belonged sub-pixel array. In step S820, a row select signal, a row control signal and a column voltage reset signal are generated. In step S830, reset sensing is performed according to a reset signal. In step S840, a sensing signal of a light source is sensed, and in step S850, a column control signal is used for outputting the sensing signal to the signal output terminal.

In other words, the sub-pixel array uses the row select signal, the row control signal, the column voltage reset signal and the column control signal to select and output the sensing signal of one of the pixels. Each sub-pixel array receives the same row select signal, the row control signal, the column voltage reset signal and the column control signal in a same timing.

In summary, according to the circuit structure of the image sensor and the sensing method thereof disclosed by the disclosure, by dividing the pixel array of the top layer into a plurality of sub-pixel arrays, each sub-pixel array has the same number of the pixels, and each sub-pixel array shares a same read circuit and an analog to digital converter. The sub-pixel arrays can be operated in parallel according to the signals of the row control circuit and the column control circuit, so as to achieve the advantage of high bandwidth of the 3D image sensing chip. Moreover, the pitch of the sub-pixel arrays is not limited to the pitch of the 3D chip stacking devices, for example, the pitch of the TSVs, and in application of the high resolution image sensor, the problem of excessive area size of the photo sensing chip is avoided.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. An image sensor, comprising:
a pixel array, comprising R×S sub-pixel arrays SP(i,j), and each sub-pixel array SP(i,j) comprising P×Q pixels PI(x,y), wherein R and S are integers greater than 1, P, Q, i, j, x and y are all integers greater than or equal to 1, i is smaller than or equal to R, j is smaller than or equal to S, x is smaller than or equal to P, and y is smaller than or equal to Q, and each pixel PI(x,y) comprises:
a photodiode, for sensing a light source to obtain a sensing signal;
a first transistor, comprising a first source/drain, a second source/drain and a gate, wherein the first source/drain of the first transistor is coupled to the photodiode, and the second source/drain of the first transistor is coupled to a node;
a second transistor, comprising a first source/drain, a second source/drain and a gate, wherein the first source/drain of the second transistor is coupled to the gate of the first transistor, the gate of the second transistor is coupled to a row control signal Rtg[n], and the second source/drain of the second transistor is coupled to a column control signal Ctg[m], wherein n and m are all integers greater than or equal to 1, n is smaller than or equal to P, and m is smaller than or equal to Q;
a third transistor, comprising a first source/drain, a second source/drain and a gate, wherein the first source/drain of the third transistor is coupled to the node, the gate of the third transistor is coupled to a reset signal Rreset[n], and the second source/drain of the third transistor is coupled to a column voltage reset signal Cvrst[m];
a fourth transistor, comprising a first source/drain, a second source/drain and a gate, wherein the gate of the fourth transistor is coupled to the node, and the second source/drain of the fourth transistor is coupled to a power voltage; and
a fifth transistor, comprising a first source/drain, a second source/drain and a gate, wherein the first source/drain of the fifth transistor is coupled to a signal output terminal, the gate of the fifth transistor is coupled to a row select signal Rsel[n], and the second source/drain of the fifth transistor is coupled to the first source/drain of the fourth transistor,
wherein the sub-pixel array SP(i,j) uses the row control signal Rtg[n], the column control signal Ctg[m], the column voltage reset signal Cvrst[m], and the row select signal Rsel[n] to select and output the sensing signal of a pixel PI(n,m).

2. The image sensor as claimed in claim 1, wherein the reset signal Rreset[n], the row control signal Rtg[n] and the row select signal Rsel[n] are generated by a row control circuit, and are transmitted to pixels of an n^{th} row in the sub-pixel array SP(i,j), and the column control signal Ctg[m] and the column voltage reset signal Cvrst[m] are generated by a column control circuit, and are transmitted to pixels of an m^{th} column in the sub-pixel array SP(i,j).

3. The image sensor as claimed in claim 2, wherein each sub-pixel array SP(i,j) receives the same reset signal Rreset[n], the row control signal Rtg[n], the column control signal Ctg[m], the column voltage reset signal Cvrst[m] and the row select signal Rsel[n] in a same timing.

4. The image sensor as claimed in claim 1, wherein the node is connected to a parasitic floating capacitor for storing the sensing signal generated by the photodiode.

5. The image sensor as claimed in claim 1, wherein the fourth transistor is a source follower transistor.

6. The image sensor as claimed in claim 1, wherein the first, the second, the third, the fourth and the fifth transistors are N-type metal oxide semiconductor transistors.

7. A sensing method of an image sensor, wherein the image sensor comprises a pixel array, the pixel array comprises R×S sub-pixel arrays SP(i,j), each sub-pixel array comprises P×Q pixels PI(x,y), and each pixel PI(x,y) comprises a photodiode, a node and a signal output terminal, each pixel is connected to a row select signal Rsel[n], a row control signal Rtg[n], a reset signal Rreset[n], a column control signal Ctg[m] and a column voltage reset signal Cvrst[m], wherein R and S are integers greater than 1, P, Q, i, j, n, m, x and y are all integers greater than or equal to 1, i is smaller than or equal to R, j is smaller than or equal to S, n and x are smaller than or equal to P, and m and y are smaller than or equal to Q, and the sensing method comprises:
after enabling the row select signal Rsel[n], the reset signal Rreset[n] sending a pulse to provide a first potential of the column voltage reset signal Cvrst[m] to the node, so that a voltage of the signal output terminal follows a voltage of the node;
after enabling the row control signal Rtg[n], the column control signal Ctg[m] sending a pulse to conduct the photodiode and the node, so that a sensing signal of the photodiode is presented at the signal output terminal; and
the reset signal Rreset[n] sending another pulse to provide a second potential of the column voltage reset signal Cvrst[m] to the node, so that the voltage of the signal output terminal is no longer related to the sensing signal of the photodiode.

8. The sensing method of the image sensor as claimed in claim 7, wherein the row select signal Rsel[n], the reset signal Rreset[n] and the row control signal Rtg[n] are generated by a row control circuit, and the column voltage reset signal Cvrst[m] and the column control signal Ctg[m] are generated by a column control circuit.

9. The sensing method of the image sensor as claimed in claim 8, wherein each sub-pixel array SP(i,j) receives the same row select signal Rsel[n], the reset signal Rreset[n], the row control signal Rtg[n], the column voltage reset signal Cvrst[m] and the column control signal Ctg[m] in a same timing.

10. A sensing method of an image sensor, comprising:
providing a pixel array, wherein the pixel array comprises R×S sub-pixel arrays SP(i,j), each sub-pixel array comprises P×Q pixels PI(x,y), and each pixel PI(x,y) is connected to a row select signal Rsel[n], a row control signal Rtg[n], a reset signal Rreset[n], a column control signal Ctg[m] and a column voltage reset signal Cvrst[m], wherein R and S are integers greater than 1, P, Q, i, j, n, m, x and y are all integers greater than or equal to 1, i is smaller than or equal to R, j is smaller than or equal to S, n and x are smaller than or equal to P, and m and y are smaller than or equal to Q;
connecting each pixel PI(x,y) of the sub-pixel array SP(i,j) to a same signal output terminal;
after enabling the row select signal Rsel[n], enabling the row control signal Rtg[n] and setting the column voltage reset signal Cvrst[m] to a first potential;
the reset signal Rreset[n] sending a pulse, and a reset signal of the pixel PI(n,m) being output to the signal output terminal; and
the column control signal Ctg[m] sending another pulse, and a sensing signal of the pixel PI(n,m) being output to the signal output terminal.

11. The sensing method of the image sensor as claimed in claim 10, wherein the row select signal Rsel[n], the row control signal Rtg[n] and the reset signal Rreset[n] are generated by a row control circuit, and the column voltage reset signal Cvrst[m] and the column control signal Ctg[m] are generated by a column control circuit.

12. The sensing method of the image sensor as claimed in claim 11, wherein each sub-pixel array SP(i,j) receives the same ow select signal Rsel[n], the row control signal Rtg[n], the reset signal Rreset[n], the column voltage reset signal Cvrst[m] and the column control signal Ctg[m] in a same timing.

13. A sensing method of an image sensor, wherein the image sensor comprises a pixel array, the pixel array comprises a plurality of sub-pixel arrays, and each sub-pixel array comprises a plurality of pixels, the sensing method comprising:
connecting each pixel to a same signal output terminal of the belonged sub-pixel array;
generating a row select signal, a row control signal and a column voltage reset signal;
performing reset sensing according to a reset signal;
sensing a sensing signal of a light source; and
using a column control signal to output the sensing signal to the signal output terminal,
wherein the sub-pixel array uses the row select signal, the row control signal, the column voltage reset signal, and the column control signal to select and output the sensing signal of one of the pixels.

14. The sensing method of the image sensor as claimed in claim 13, wherein the row select signal, the row control signal and the reset signal are generated by a row control circuit, and the column voltage reset signal and the column control signal are generated by a column control circuit.

15. The sensing method of the image sensor as claimed in claim 14, wherein each sub-pixel array receives the same row select signal, the row control signal, the column voltage reset signal and the column control signal in a same timing.
